(19) United States
(12) Patent Application Publication
(10) Pub. No.: US 2026/0190806 A1
(43) Pub. Date: Jul. 2, 2026

(54) DISPLAY DEVICE

(71) Applicant: LG Display Co., Ltd., Seoul (KR)

(72) Inventors: ByungJune MUN, Gumi-si (KR); Hyunjik BAE, Daegu (KR)

(73) Assignee: LG Display Co., Ltd., Seoul (KR)

(21) Appl. No.: 19/245,191

(22) Filed: Jun. 20, 2025

(30) Foreign Application Priority Data
Dec. 30, 2024 (KR) 10-2024-0201248

(51) Int. Cl. H10K 59/80; H10H 29/30; H10H 29/37; H10H 29/855; H10K 59/122; H10K 59/126; H10K 59/35

(52) U.S. Cl. CPC H10K 59/879; H10H 29/362; H10H 29/37; H10H 29/8552; H10K 59/122; H10K 59/126; H10K 59/351; H10K 59/8792

(57) ABSTRACT

Provided is a display device. The display device includes a substrate having a plurality of sub-pixels defined, a plurality of first light-emitting elements disposed in each of the plurality of sub-pixels, a plurality of second light-emitting elements disposed in each of the plurality of sub-pixels, a plurality of first light-blocking patterns overlapping centers of the plurality of second light-emitting elements on the plurality of second light-emitting elements, a plurality of first optical members disposed on the plurality of first light-emitting elements and refracting light from the plurality of first light-emitting elements and a plurality of second optical members disposed on the plurality of second light-emitting elements and refracting light from the plurality of second light-emitting elements.

### CROSS-REFERENCE TO RELATED APPLICATIONS

This application claims the priority of Korean Patent Application No. 10-2024-0201248 filed on Dec. 30, 2024, in the Korean Intellectual Property Office, the disclosure of which is incorporated herein by reference.

### BACKGROUND

### Technical Field

The present disclosure relates to a display device and more particularly, to a display device capable of facilitating viewing angle control.

### Discussion of the Related Art

As technology in modern society develops, display devices are used in various ways to provide information to users. Display devices are included in electronic signs that simply transmit visual information in one direction, as well as various electronic devices that require higher technology to confirm a user input and provide information in response to the confirmed input.

For example, display devices may be included in vehicles to provide various information to a driver and passengers of the vehicle. However, the display device of the vehicle needs to display content appropriately so as not to interfere with vehicle operations. For example, the display device needs to limit display of content that may reduce concentration on driving while the vehicle is in operation.

### SUMMARY

Accordingly, embodiments of the present disclosure are directed to a display device that substantially obviates one or more of the problems due to limitations and disadvantages of the related art.

An aspect of the present disclosure is to provide a display device with improved brightness deviation according to viewing angle.

Another aspect of the present disclosure is to provide a display device capable of improving the visibility of a displayed image.

Still another aspect of the present disclosure is to provide a display device that may facilitate viewing angle control by compensating for light in a side direction where brightness is reduced compared to a front surface when providing content at a narrow viewing angle.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display device comprises a substrate having a plurality of sub-pixels defined, a plurality of first light-emitting elements disposed in each of the plurality of sub-pixels, a plurality of second light-emitting elements disposed in each of the plurality of sub-pixels, a plurality of first light-blocking patterns overlapping centers of the plurality of second light-emitting elements on the plurality of second light-emitting elements, a plurality of first optical members disposed on the plurality of first light-emitting elements and refracting light from the plurality of first light-emitting elements and a plurality of second optical members disposed on the plurality of second light-emitting elements and refracting light from the plurality of second light-emitting elements.

According to another aspect of the present disclosure, there is provided a display device. The display device comprises a substrate having a plurality of sub-pixels defined, a plurality of light-emitting elements disposed in each of the plurality of sub-pixels, a bank defining a light-emitting area of the plurality of light-emitting elements on the substrate, a plurality of optical members overlapping the light-emitting area of the plurality of light-emitting elements on the plurality of light-emitting elements and a plurality of first light-blocking patterns disposed in each of the plurality of sub-pixels on the plurality of light-emitting elements, wherein the plurality of light-emitting elements are disposed in each of the plurality of sub-pixels and include a plurality of first light-emitting elements and a plurality of second light-emitting elements that emit the same color, and the plurality of first light-blocking patterns overlap the center of the light-emitting area of the plurality of second light-emitting elements of the light-emitting area of the plurality of first light-emitting elements and the light-emitting area of the plurality of second light-emitting elements.

Other detailed matters of the exemplary embodiments are included in the detailed description and the drawings.

The display device according to an embodiment of the present disclosure can, when providing content at a narrow viewing angle, form a uniform brightness distribution according to the viewing angle, thereby clearly defining an area that limits an image.

The display device according to an embodiment of the present disclosure can improve viewing angle required in a narrow viewing angle mode.

The display device according to an embodiment of the present disclosure does not increase the overall brightness of pixels to improve side brightness, but instead separately disposes pixels for improving the side brightness, thereby suppressing deterioration of pixels, enabling low-power operation, and improving the lifespan of the display device.

It is to be understood that both the foregoing general description and the following detailed description are exemplary and explanatory and are intended to provide further explanation of the inventive concepts as claimed.

### BRIEF DESCRIPTION OF DRAWINGS

The accompanying drawings, which are included to provide a further understanding of the disclosure and are incorporated in and constitute a part of this application, illustrate embodiments of the disclosure and together with the description serve to explain various principles. In the drawings:

FIG. 1 is an exemplary view of a display device according to one embodiment of the present disclosure.

FIG. 2 is a functional block diagram of the display device according to one embodiment of the present disclosure.

FIG. 3 is a circuit diagram illustrating an example of a pixel circuit included in the display device of FIG. 2.

FIG. 4 is an enlarged plan view illustrating disposition of optical members included in the display device according to one embodiment of the present disclosure.

FIG. 5 is a cross-sectional view taken along line I-I′ of FIG. 4.

FIG. 6 is a cross-sectional view taken along line II-II′ of FIG. 4.

FIG. 7 is a graph for explaining brightness according to viewing angle of the display device according to one embodiment of the present disclosure.

FIG. 8 is an enlarged plan view illustrating disposition of optical members included in a display device according to another embodiment of the present disclosure.

FIG. 9 is a cross-sectional view taken along line III-III′ of FIG. 8.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, an exemplary embodiment of the present disclosure will be described in detail with reference to the drawings.

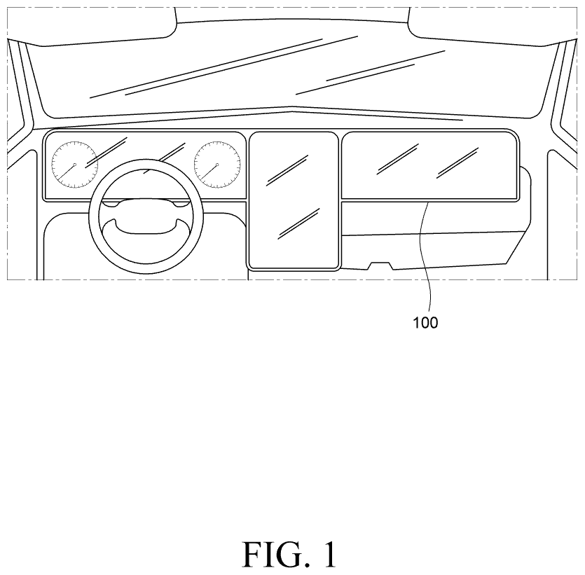

FIG. 1 is an exemplary view of a display device according to one embodiment of the present disclosure.

Referring to FIG. 1, a display device 100 may be disposed on at least a portion of a dashboard of a vehicle. The dashboard of the vehicle may include a configuration that is disposed in front of a front seat (for example, driver's seat, passenger seat) of the vehicle. For example, the dashboard of the vehicle may have input configurations disposed for operating various functions (for example, air conditioning, audio system, navigation system) inside the vehicle.

The display device 100 may be disposed on the dashboard of a vehicle and may function as an input unit for operating at least a portion of various functions of the vehicle. The display device 100 may provide various information related to the vehicle, for example, vehicle operation information (for example, current speed of the vehicle, remaining fuel amount, driving distance), information on vehicle parts (for example, damage to vehicle tires), or the like.

The display device 100 may be disposed across the driver's seat and the passenger seat disposed in the front seat of the vehicle. Users of the display device 100 may include the driver of the vehicle and the passenger riding in the passenger seat. Both the driver and the passenger of the vehicle may use the display device 100.

The display device 100 illustrated in FIG. 1 may only illustrate a portion of the display device. The display device 100 illustrated in FIG. 1 may illustrate a display panel among various components included in the display device 100. Specifically, for example, the display device 100 illustrated in FIG. 1 may illustrate at least a portion of a display area and a non-display area of the display panel. Configurations of the display device 100 other than the configuration illustrated in FIG. 1 may be mounted inside (or at least a portion of) the vehicle.

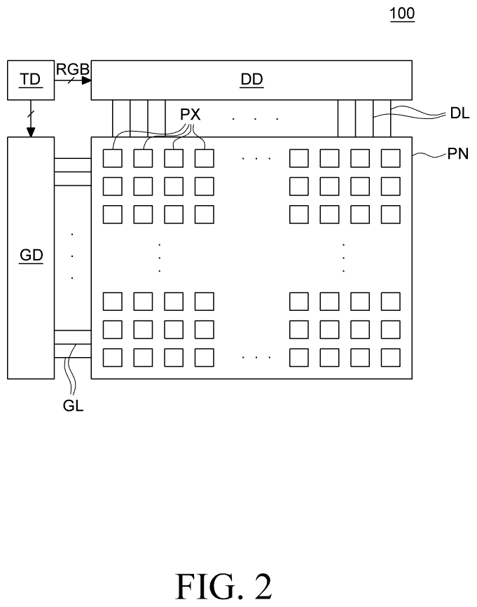

FIG. 2 is a functional block diagram of the display device according to one embodiment of the present disclosure.

An electroluminescent display device may be applied as the display device according to one embodiment of the present disclosure. The electroluminescent display device may be an organic light emitting diode (OLED) display device, a quantum-dot light emitting diode (QD) display device, or an inorganic light emitting diode (ILD) display device.

Referring to FIG. 2, the display device 100 may include a display panel PN, a data driving circuit DD, a gate driving circuit GD, and a timing controller TD.

The display panel PN may generate an image to be provided to a user. For example, the display panel PN may generate and display an image to be provided to a user through a plurality of pixels PX each having a pixel circuit disposed therein.

The data driving circuit DD, the gate driving circuit GD, and the timing controller TD may provide signals for the operation of each pixel PX through signal lines. For example, signal lines for providing signals for the operation of each pixel PX may include a plurality of data lines DL and a plurality of gate lines GL.

The plurality of data lines DL is disposed in a column direction and may include a plurality of lines connected to pixels PX disposed in one column direction, and the plurality of gate lines GL are disposed in a row direction and may include a plurality of lines connected to pixels PX disposed in one row direction.

In some cases, the display device 100 may further include a power unit. In this case, a signal for the operation of the pixel PX may be provided through a power line connecting the power unit and the display panel PN. In some embodiments, the power unit may provide power to the data driving circuit DD and the gate driving circuit GD. The data driving circuit DD and the gate driving circuit GD may be driven based on the power provided from the power unit.

For example, the data driving circuit DD may apply the data signal to each pixel PX through the plurality of data lines DL, the gate driving circuit GD may apply the gate signal to each pixel PX through the plurality of gate lines GL, and the power unit may supply the power voltage to each pixel PX through a power voltage supply line.

The timing controller TD may control the data driving circuit DD and the gate driving circuit GD. For example, the timing controller TD may rearrange digital video data input from the outside to match the resolution of the display panel PN and supply the digital video data to the data driving circuit DD.

The data drive circuit DD may convert digital video data input from the timing controller TD into analog data voltage based on the data control signal and supply the converted analog data to the plurality of data lines DL.

The gate driving circuit GD may generate a scan signal and a light emission signal based on the gate control signal. For example, the gate driving circuit GD may include a scan driving unit and a light emission signal driving unit. The scan driving unit may generate a scan signal in a row-sequential manner and supply the generated scan signal to the scan lines to drive at least one or more scan lines connected to each pixel row. The light emission signal driving unit may generate a light emission signal in a row-sequential manner and supply the generated light emission signal to the light emission signal lines to drive at least one or more light emission signal lines connected to each pixel row.

According to an embodiment, the gate driving circuit GD may be disposed in the display panel PN in a gate-driver in panel (GIP) manner. For example, the gate driving circuit GD may be divided into a plurality of pieces and disposed on at least two side surfaces of the display panel PN, respectively.

The display panel PN may include the display area and the non-display area surrounding the display area.

The display area of the display panel PN may include the plurality of pixels PX disposed in the row direction and the column direction. For example, the plurality of pixels PX may be disposed in an area where the plurality of data lines DL and the plurality of gate lines GL intersect.

A pixel PX may include a plurality of sub-pixels that emit different colors. For example, a pixel PX may use three sub-pixels to implement blue, red, and green. However, this is not limited to the above, and in some cases, the pixel PX may further include the sub-pixels to implement a specific color, for example, white.

In the pixel PX, the area that implements blue may be referred to as a blue sub-pixel, the area that implements red may be referred to as a red sub-pixel, and the area that implements green may be referred to as a green sub-pixel.

Each of the plurality of pixels PX may include a first light-emitting element, a second light-emitting element, and a third light-emitting element that emit the same color.

Each of the plurality of pixels PX may include a first optical member that refracts light from the first light-emitting element in a specific direction, a second optical member that refracts light from the second light-emitting element in a specific direction, and a third optical member that refracts light from the third light-emitting element in a specific direction. For example, the first optical member, the second optical member, and the third optical member may each be implemented as a lens, but the embodiments of the present disclosure are not limited thereto.

For example, the first optical member and the second optical member may be disposed in an optical area that provides light in a first range to form a first viewing angle, and the third optical member may be disposed in an optical area that provides light in a second range to form a second viewing angle. The second range may correspond to a wider range than the first range. Accordingly, the first optical member, the second optical member, and the third optical member may limit the viewing angle of each of the plurality of pixels PX.

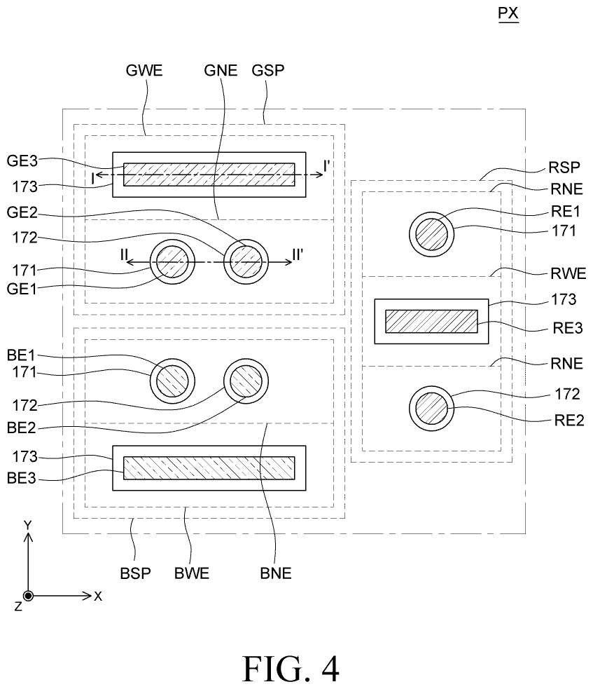

Detailed descriptions of the first optical member, the second optical member, and the third optical member will be described later with reference to FIGS. 4 to 6.

The non-display area may be disposed along the perimeter of the display area. Various components for driving the pixel circuit disposed in the pixel PX may be disposed in the non-display area. For example, at least a portion of the gate driving circuit GD may be disposed in the non-display area. The non-display area may be referred to as a bezel area.

When the display panel PN is used in a vehicle as described with reference to FIG. 1, the field of view of at least some areas of the display panel PN may need to be restricted depending on the user's needs. For example, in the case of an image displayed in an area of the display panel PN that provides entertainment functions and seat information for a passenger sitting in the passenger seat, since the image may interfere with the driver's driving, the field of view of the image displayed in that area may need to be restricted depending on the user's needs.

Accordingly, each pixel PX included in the display panel PN may be driven in a first mode or a second mode depending on the driving mode. For example, when the pixel PX is driven in the first mode, the first light-emitting element and the second light-emitting element included in the pixel PX emit light based on the selection signal, and light from the first light-emitting element and the second light-emitting element is provided to the first range through the first optical member and the second optical member to form the first viewing angle, for example, a narrow viewing angle. In addition, when the pixel PX is driven in the second mode, the third light-emitting element included in the pixel PX emits light based on the selection signal, and light from the third light-emitting element is provided to the second range through the third optical member to form the second viewing angle, for example, a wide viewing angle. Here, the first mode may correspond to a mode in which the corresponding pixel PX is driven in a narrow field of view mode (private mode), and the second mode may correspond to a mode in which the corresponding pixel PX is controlled in a wide field of view mode (share mode).

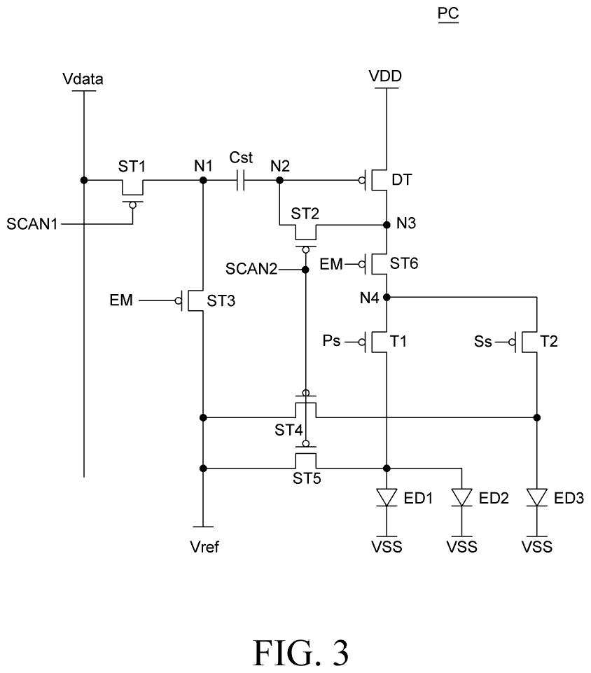

FIG. 3 is a circuit diagram illustrating an example of a pixel circuit included in the display device of FIG. 2.

Meanwhile, a pixel circuit PC illustrated in FIG. 3 represents one embodiment of the pixel circuit corresponding to each of the plurality of pixels PX included in the display device 100 described with reference to FIG. 2.

Referring to FIG. 3, at least some of a plurality of transistors included in the pixel circuit PC may be n-type transistors or p-type transistors. In the case of p-type transistors, the low-level voltage of each driving signal may mean a voltage that turns on the TFTs, and the high-level voltage of each driving signal may mean a voltage that turns off the TFTs.

Here, the low-level voltage may correspond to a pre-specified voltage that is lower than the high-level. For example, the low-level voltage may include a voltage that falls within a range of −8 V to −12 V. The high-level voltage may correspond to a pre-specified voltage that is higher than the low-level voltage. For example, the high-level voltage may include a voltage that falls within a range of 12 V to 16 V. In some embodiments, the low-level voltage may be referred to as a first voltage, and the high-level voltage may be referred to as a second voltage. In such a case, the first voltage may be a lower value than the second voltage.

The pixel circuit PC may include a driving transistor DT, a plurality of switching transistors ST1 to ST6, a first transistor T1, a second transistor T2, a storage capacitor Cst, and a plurality of light-emitting elements ED1, ED2, and ED3.

The driving transistor DT may control a driving current applied to the plurality of light-emitting elements ED1, ED2, and ED3 according to a source-gate voltage. The driving transistor DT may include a source electrode connected to a high-potential power line providing a high-potential power voltage VDD, a gate electrode connected to a second node N2, and a drain electrode connected to a third node N3.

A first switching transistor ST1 may apply a data voltage Vdata from the data line DL to a first node N1. The first switching transistor ST1 may include a source electrode connected to the data line DL, a drain electrode connected to the first node N1, and a gate electrode connected to a first scan signal line to which a first scan signal SCAN1 is applied. The first switching transistor ST1 may be turned on or off by the first scan signal SCAN1. Accordingly, the first switching transistor ST1 may apply the data voltage Vdata from the data line DL to the first node N1 in response to the first scan signal SCAN1 of a low-level, which is a turn-on level.

The second switching transistor ST2 may diode-connect the gate electrode and the drain electrode of the driving transistor DT. The second switching transistor ST2 may include a drain electrode connected to the second node N2, a source electrode connected to the third node N3, and a gate electrode connected to a second scan signal line to which a second scan signal SCAN2 is applied. The second switching transistor ST2 may be turned on or off by the second scan signal SCAN2. Accordingly, the second switching transistor ST2 may diode-connect the gate electrode and the drain electrode of the driving transistor DT in response to the second scan signal SCAN2 of a low-level, which is a turn-on level.

A third switching transistor ST3 may apply a reference voltage Vref to the first node N1. The third switching transistor ST3 may include a source electrode connected to a reference voltage line providing the reference voltage Vref, a drain electrode connected to the first node N1, and a gate electrode connected to a light emission signal line to which a light emission signal EM is applied. The third switching transistor ST3 may be turned on or off by the light emission signal EM. Accordingly, the third switching transistor ST3 may transfer the reference voltage Vref to the first node N1 in response to the light emission signal EM of a low-level, which is a turn-on level.

A fourth switching transistor ST4 may apply the reference voltage Vref to the anode electrode of the third light-emitting element ED3. The fourth switching transistor ST4 may include a source electrode connected to a reference voltage line providing the reference voltage Vref, a drain electrode connected to the anode electrode of the third light-emitting element ED3, and a gate electrode connected to a second scan signal line to which the second scan signal SCAN2 is applied. The fourth switching transistor ST4 may be turned on or off by the second scan signal SCAN2. Accordingly, the fourth switching transistor ST4 may apply the reference voltage Vref to the anode electrode of the third light-emitting element ED3 in response to the second scan signal SCAN2 of a low-level, which is a turn-on level.

A fifth switching transistor ST5 may apply the reference voltage Vref to the anode electrode of the first light-emitting element ED1 and the anode electrode of the second light-emitting element ED2. The fifth switching transistor ST5 may include a source electrode connected to a reference voltage line providing the reference voltage Vref, a drain electrode connected to the anode electrode of the first light-emitting element ED1 and the anode electrode of the second light-emitting element ED2, and a gate electrode connected to a second scan signal line to which a second scan signal SCAN2 is applied. The fifth switching transistor ST5 may be turned on or off by the second scan signal SCAN2. Accordingly, the fifth switching transistor ST5 may apply the reference voltage Vref to the anode electrode of the first light-emitting element ED1 and the anode electrode of the second light-emitting element ED2 in response to the second scan signal SCAN2 of a low-level, which is a turn-on level.

A sixth switching transistor ST6 may form a current path between the driving transistor DT and any one of the plurality of light-emitting elements ED1, ED2, and ED3. The sixth switching transistor ST6 may include a source electrode connected to the third node N3, a drain electrode connected to a fourth node N4, and a gate electrode connected to a light emission signal line to which a light emission signal EM is applied. The sixth switching transistor ST6 may be turned on or off by the light emission signal EM. Accordingly, the sixth switching transistor ST6 may form a current path between the driving transistor DT and one of the plurality of light-emitting elements ED1, ED2, and ED3 by electrically connecting the third node N3 and the fourth node N4 in response to the light emission signal EM of a low-level that is a turn-on level.

The storage capacitor Cst may include a first electrode connected to the first node N1 and a second electrode connected to the second node N2. One electrode of the storage capacitor Cst may be connected to the gate electrode of the driving transistor DT, and the other electrode of the storage capacitor Cst may be connected to the first switching transistor ST1. The storage capacitor Cst may store a constant voltage to maintain the voltage of the gate electrode of the driving transistor DT constant while one of the plurality of light-emitting elements ED1, ED2, and ED3 emits light.

The first light-emitting element ED1 and the second light-emitting element ED2 may be connected between the first transistor T1 that is turned on or off by a first selection signal Ps and a low-potential power line that provides a low-potential power voltage VSS. For example, the first light-emitting element ED1 and the second light-emitting element ED2 may be connected in parallel to the first transistor T1 and the low-potential power line that provides the low-potential power voltage VSS. The third light-emitting element ED3 may be connected between the second transistor T2 that is turned on or off by a second selection signal Ss and the low-potential power line that provides the low-potential power voltage VSS.

The first transistor T1 may generate a current path of the first driving current passing through the first light-emitting element ED1 and the second light-emitting element ED2, and the second transistor T2 may generate a current path of the second driving current passing through the third light-emitting element ED3.

The first transistor T1 is connected between the fourth node N4 and the first light-emitting element ED1 and between the fourth node N4 and the second light-emitting element ED2, and the gate electrode of the first transistor T1 may be connected to a first selection signal line that provides the first selection signal Ps. When the pixel PX to which the pixel circuit PC is applied is driven in the first mode, which is the narrow field of view mode, the first selection signal Ps may be supplied to the gate electrode of the first transistor T1 to turn on the first transistor T1. Accordingly, a current path of a first driving current passing through the first light-emitting element ED1 and the second light-emitting element ED2 is formed, so that the first light-emitting element ED1 and the second light-emitting element ED2 may emit light. Meanwhile, the first transistor T1 may also be referred to as a first light-emitting control transistor that controls the light emission of the first light-emitting element ED1 and the second light-emitting element ED2.

The second transistor T2 is connected between the fourth node N4 and the third light-emitting element ED3, and the gate electrode of the second transistor T2 may be connected to a second selection signal line that provides the second selection signal Ss. When the pixel PX to which the pixel circuit PC is applied is driven in the second mode, which is the wide field of view mode, the second selection signal Ss may be supplied to the gate electrode of the second transistor T2 to turn on the second transistor T2. Accordingly, a current path of the second driving current passing through the third light-emitting element ED3 is formed, so that the third light-emitting element ED3 may emit light. Meanwhile, the second transistor T2 may also be referred to as a second light-emitting control transistor that controls light emission of the third light-emitting element ED3.

In this case, the first light-emitting element ED1, the second light-emitting element ED2, or the third light-emitting element ED3 may be connected to another component of the pixel circuit PC, for example, the driving transistor DT, via the first transistor T1 or the second transistor T2 that is turned on according to the driving mode. For example, the first light-emitting element ED1 and the second light-emitting element ED2 are connected to the driving transistor DT via the first transistor T1 that is turned on in the first mode, and may provide light in the first mode, that is, the narrow field of view mode, with the first viewing angle, that is, a narrow field of view, by the first driving current. In addition, the third light-emitting element ED3 is connected to the driving transistor DT via the second transistor T2 that is turned on in the second mode, and may provide light in the second mode, that is, the wide field of view mode, with the second viewing angle, that is, the wide field of view, by the second driving current. Here, the driving mode may be specified by user input or determined when a pre-specified condition is satisfied.

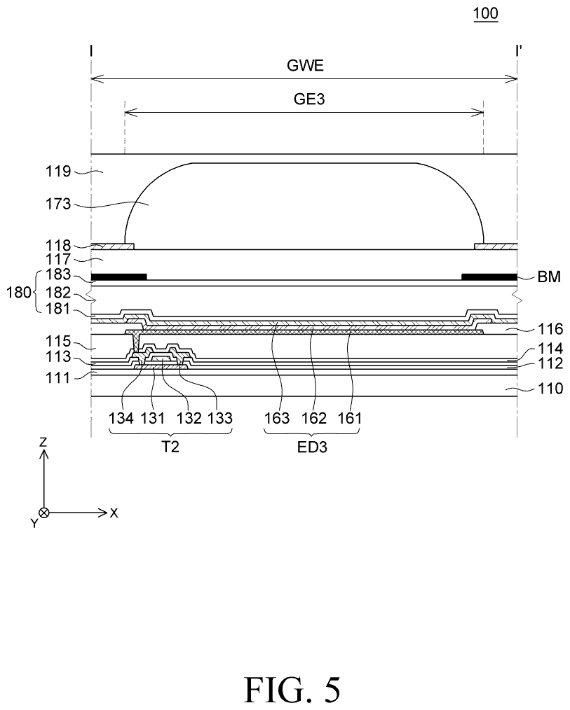

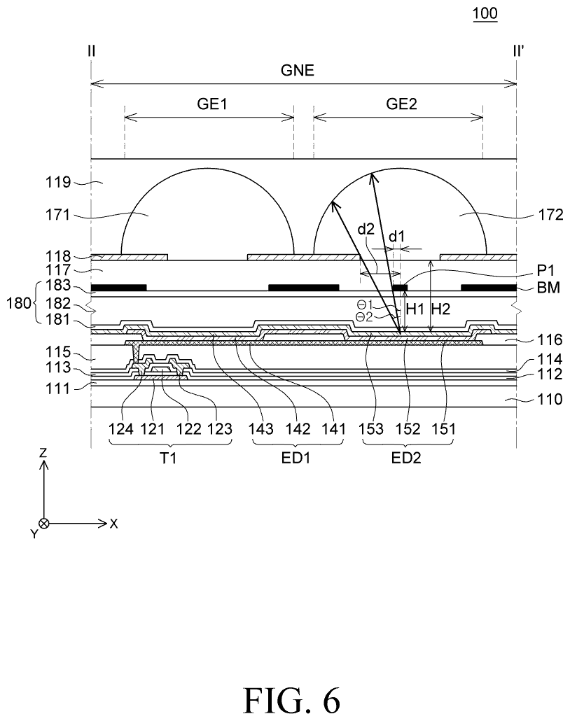

FIG. 4 is an enlarged plan view illustrating the disposition of an optical member included in a display device according to one embodiment of the present disclosure. FIG. 5 is a cross-sectional view taken along line I-I′ of FIG. 4. FIG. 6 is a cross-sectional view taken along line II-II′ of FIG. 4.

Meanwhile, FIG. 4 illustrates a plane of the pixel PX in a case where the pixel PX includes three sub-pixels, for example, a first sub-pixel RSP, a second sub-pixel GSP, and a third sub-pixel BSP.

In addition, FIG. 5 illustrates a pixel PX in which a third optical member 173 is disposed as an embodiment of the display device 100 cut along line I-I′ of FIG. 4, and FIG. 6 illustrates the pixel PX in which a first optical member 171 and a second optical member 172 are disposed as an embodiment of the display device 100 cut along line II-II′ of FIG. 4.

Meanwhile, for convenience of explanation, in FIGS. 5 and 6, only the areas corresponding to a first optical area GNE and a second optical area GWE of the second sub-pixel GSP among the three sub-pixels RSP, GSP, and BSP illustrated in FIG. 4 are illustrated, but other sub-pixels RSP and BSP may also be formed with the same configuration.

Meanwhile, for convenience of explanation, the horizontal direction on the plane is illustrated as a first direction X and the vertical direction on the plane is illustrated as a second direction Y hereinafter. In addition, the normal direction of the surface defined by the first direction X and the second direction Y, for example, the thickness direction of the display device 100, may be defined as a third direction Z.

Referring to FIG. 4, the pixel PX may include the plurality of sub-pixels RSP, GSP, and BSP that represent different colors. For example, the pixel PX may include a first sub-pixel RSP that implements red, a second sub-pixel GSP that implements green, and a blue sub-pixel BSP that implements blue. According to an embodiment, the first sub-pixel RSP may be named a red sub-pixel, the second sub-pixel GSP may be named a green sub-pixel, and the third sub-pixel BSP may be named a blue sub-pixel. The pixel circuit PC described with reference to FIG. 3 may be disposed in each of the plurality of sub-pixels RSP, GSP, and BSP included in the pixel PX.

The plurality of sub-pixels RSP, GSP, and BSP may include first optical areas RNE, GNE, and BNE and second optical areas RWE, GWE, and BWE providing different viewing angles, respectively.

The first optical areas RNE, GNE, and BNE of the corresponding pixel PX of the sub-pixels RSP, GSP, and BSP may operate independently from the second optical areas RWE, GWE, and BWE. For example, the sub-pixels RSP, GSP, and BSP may include the first light-emitting element ED1 and the second light-emitting element ED2 disposed in the first optical areas RNE, GNE, and BNE of the corresponding sub-pixels RSP, GSP, and BSP, and the third light-emitting element ED3 disposed in the second optical areas RWE, GWE, and BWE. In this case, the third light-emitting element ED3 may emit light independently from the first light-emitting element ED1 and the second light-emitting element ED2.

The number of light-emitting elements defined within the first optical areas RNE, GNE, and BNE for the sub-pixels RSP, GSP, and BSP may be greater than the number of light-emitting elements defined within the second optical areas RWE, GWE, and BWE. In this case, the efficiency deviations of the first light-emitting elements ED1 and the second light-emitting elements ED2 respectively positioned on the first optical areas RNE, GNE, and BNE may be mutually complemented.

For example, in one pixel PX, the first light-emitting element ED1 and the second light-emitting element ED2 disposed in the first optical area RNE of the first sub-pixel RSP, the third light-emitting element ED3 disposed in the second optical area RWE of the first sub-pixel RSP, the first light-emitting element ED1 and the second light-emitting element ED2 disposed in the first optical area GNE of the second sub-pixel GSP, the third light-emitting element ED3 disposed in the second optical area (GWE) of the second sub-pixel GSP, the first light-emitting element ED1 and the second light-emitting element ED2 disposed in the first optical area BNE of the third sub-pixel BSP, and the third light-emitting element ED3 disposed in the second optical area BWE of the third sub-pixel BSP may be disposed.

Referring to FIG. 4, in the first optical areas RNE, GNE, and BNE of the sub-pixels RSP, GSP, and BSP, at least one first optical member 171 may be disposed to overlap the first light-emitting areas RE1, GE1, and BE1 of the first light-emitting element ED1 and at least one second optical member 172 may be disposed to overlap the second light-emitting areas RE2, GE2, and BE2 of the second light-emitting element ED2. In the second optical areas RWE, GWE, and BWE of the sub-pixels RSP, GSP, and BSP, at least one third optical member 173 may be disposed to overlap the third light-emitting areas RE3, GE3, and BE3 of the third light-emitting element ED3. In this case, the first optical areas RNE, GNE, and BNE may have the first viewing angle smaller than the second viewing angle, and the second optical areas RWE, GWE, and BWE may have the second viewing angle.

Referring to FIGS. 4 and 5 and 6 together, the display device 100 according to an embodiment of the present disclosure may include a substrate 110, a buffer layer 111, a gate insulating layer 112, an interlayer insulating layer 113, a lower protective layer 114, an overcoat layer 115, a bank 116, a first transistor T1, a second transistor T2, a first light-emitting element ED1, a second light-emitting element ED2, a third light-emitting element ED3, an encapsulating member 180, a touch insulating layer 117, a black matrix BM, a first light-blocking pattern P1, a barrier layer 118, a first optical member 171, a second optical member 172, a third optical member 173, and an optical member protective layer 119.

The substrate 110 may include an insulating material. The substrate 110 may include a transparent material. For example, the substrate 110 may include glass or plastic.

The buffer layer 111 may be disposed on the substrate 110. The buffer layer 111 may include an insulating material. For example, the buffer layer 111 may include an inorganic insulating material such as silicon oxide SiOₓ and silicon nitride SiNₓ. The buffer layer 111 may have a multilayer structure. For example, the buffer layer 111 may have a stacked structure of a layer made of silicon nitride SiNₓ and a layer made of silicon oxide SiOₓ.

The buffer layer 111 may be positioned between the substrate 110 and the driving portions of the sub-pixels RSP, GSP, and BSP. The buffer layer 111 may suppress contamination by the substrate 110 during the formation process of the driving portion. For example, the upper surface of the substrate 110 facing the driving portions of the sub-pixels RSP, GSP, and BSP may be covered by the buffer layer 111. The driving portions of the sub-pixels RSP, GSP, and BSP may be positioned on the buffer layer 111.

The gate insulating layer 112 may be disposed on the buffer layer 111. The gate insulating layer 112 may include an insulating material. For example, the gate insulating layer 112 may include an inorganic insulating material such as silicon oxide SiO and silicon nitride SiN. The gate insulating layer 112 may include a material having a high dielectric constant. For example, the gate insulating layer 112 may include a High-K material such as hafnium oxide HfO. The gate insulating layer 112 may have a multilayer structure.

The gate insulating layer 112 may extend between semiconductor layers 121 and 131 of the transistors T1 and T2 and gate electrodes 122 and 132. For example, the gate electrodes 122 and 132 of the first transistor T1 and the second transistor T2 may be insulated from the semiconductor layers 121 and 131 of the first transistor T1 and the second transistor T2 by the gate insulating layer 112. The gate insulating layer 112 may cover the semiconductor layers 121 and 131 of the sub-pixels RSP, GSP, and BSP. The gate electrodes 122 and 132 of the first transistor T1 and the second transistor T2 may be positioned on the gate insulating layer 112.

The interlayer insulating layer 113 may be disposed on the gate insulating layer 112. The interlayer insulating layer 113 may include an insulating material. For example, the interlayer insulating layer 113 may include an inorganic insulating material such as silicon oxide SiO and silicon nitride SiN. The interlayer insulating layer 113 may extend between the gate electrodes 122 and 132 and the source electrodes 123 and 133 of the first transistor T1 and the second transistor T2, and between the gate electrodes 122 and 132 and the drain electrodes 124 and 134. For example, the source electrodes 123 and 133 and the drain electrodes 124 and 134 of the first transistor T1 and the second transistor T2 may be insulated from the gate electrodes 122 and 132 by the interlayer insulating layer 113. The interlayer insulating layer 113 may cover the gate electrodes 122 and 132 of the first transistor T1 and the second transistor T2. The source electrodes 123 and 133 and the drain electrodes 124 and 134 of each of the sub-pixels RSP, GSP, and BSP may be positioned on the interlayer insulating layer 113. The gate insulating layer 112 and the interlayer insulating layer 113 may expose the source area and the drain area of the semiconductor layer 121 and 131 positioned in each of the sub-pixels RSP, GSP, and BSP.

The lower protective layer 114 may be disposed on the interlayer insulating layer 113. The lower protective layer 114 may include an insulating material. For example, the lower protective layer 114 may include an inorganic insulating material such as silicon oxide SiO and silicon nitride SiN.

The lower protective layer 114 may suppress damage to the driving portion due to external moisture and impact. The lower protective layer 114 may extend along the surfaces of the first transistor T1 and the second transistor T2. The lower protective layer 114 may be in contact with the interlayer insulating layer 113 on the outside of the driving portion located in each of the sub-pixels RSP, GSP, and BSP.

The overcoat layer 115 may be disposed on the lower protective layer 114. The overcoat layer 115 may include an insulating material. The overcoat layer 115 may include a different material from the lower protective layer 114. For example, the overcoat layer 115 may include an organic insulating material.

The overcoat layer 115 may eliminate the step difference caused by the driving portion of each of the sub-pixels RSP, GSP, and BSP. For example, the upper surface of the overcoat layer 115 opposing the substrate 110 may be a flat surface.

The first transistor T1 and the second transistor T2 may be disposed on the substrate 110. The first transistor T1 may be electrically connected between a drain electrode of the driving transistor DT and a first lower electrode 141 of the first light-emitting element ED1. In addition, the first transistor T1 may be electrically connected between the drain electrode of the driving transistor DT and a second lower electrode 151 of the second light-emitting element ED2. The second transistor T2 may be electrically connected between the drain electrode of the driving transistor DT and a third lower electrode 161 of the third light-emitting element ED3.

The first transistor T1 may include the first semiconductor layer 121, the first gate electrode 122, the first source electrode 123, and the first drain electrode 124. The first transistor T1 may have the same structure as the switching transistor and the driving transistor.

For example, the first semiconductor layer 121 may be positioned between the buffer layer 111 and the gate insulating layer 112, and the first gate electrode 122 may be positioned between the gate insulating layer 112 and the interlayer insulating layer 113. The first source electrode 123 and the first drain electrode 124 may be positioned between the interlayer insulating layer 113 and the lower protective layer 114. The first gate electrode 122 may overlap a channel area of the first semiconductor layer 121. The first source electrode 123 may be electrically connected to the source area of the first semiconductor layer 121. The first drain electrode 124 may be electrically connected to the drain area of the first semiconductor layer 121.

The second transistor T2 may include the second semiconductor layer 131, the second gate electrode 132, the second source electrode 133, and the second drain electrode 134. For example, the second semiconductor layer 131 may be located in the same layer as the first semiconductor layer 121, the second gate electrode 132 may be located in the same layer as the first gate electrode 122, and the second source electrode 133 and the second drain electrode 134 may be located in the same layer as the first source electrode 123 and the first drain electrode 124.

The first light-emitting element ED1, the second light-emitting element ED2, and the third light-emitting element ED3 of each of the sub-pixels RSP, GSP, and BSP may be disposed on the overcoat layer 115 of the corresponding sub-pixels RSP, GSP, and BSP.

The first light-emitting element ED1 may emit light representing a specific color. For example, the first light-emitting element ED1 may include a first lower electrode 141, a first light-emitting layer 142, and a first upper electrode 143 sequentially stacked on the substrate 110.

The first lower electrode 141 may include a conductive material. The first lower electrode 141 may include a material having high reflectivity. For example, the first lower electrode 141 may include a metal such as aluminum Al and silver Ag. The first lower electrode 141 may have a multilayer structure. For example, the first lower electrode 141 may have a structure in which a reflective electrode made of a metal is positioned between transparent electrodes made of a transparent conductive material such as ITO (Indium tin oxide) and IZO ((Indium Zinc Oxide). The first lower electrode 141 may be electrically connected to the first drain electrode 124 of the first transistor T1 through a contact hole penetrating the lower protective layer 114 and the overcoat layer 115.

The first light-emitting layer 142 may generate light having a brightness corresponding to a voltage difference between the first lower electrode 141 and the first upper electrode 143. For example, the first light-emitting layer 142 may include an emission material layer EML including an emission material. The emission material may include an organic material, an inorganic material, or a hybrid material.

The first light-emitting layer 142 may have a multilayer structure. For example, the first light-emitting layer 142 may further include at least one of a hole injection layer HIL, a hole transport layer HTL, an electron transport layer ETL, and an electron injection layer EIL.

The first upper electrode 143 may include a conductive material. The first upper electrode 143 may include a different material from the first lower electrode 141. The transmittance of the first upper electrode 143 may be higher than the transmittance of the first lower electrode 141. For example, the first upper electrode 143 may be a transparent electrode made of a transparent conductive material such as ITO and IZO. Accordingly, in the display device 100 according to the embodiment of the present disclosure, light generated by the first light-emitting layer 142 may be emitted through the first upper electrode 143.

The second light-emitting element ED2 may implement the same color as the first light-emitting element ED1 disposed in the same sub-pixels RSP, GSP, and BSP. For example, the second light-emitting element ED2 may include the second lower electrode 151, a second light-emitting layer 152, and a second upper electrode 153 sequentially stacked on a substrate 110.

The second lower electrode 151 may correspond to the first lower electrode 141, the second light-emitting layer 152 may correspond to the first light-emitting layer 142, and the second upper electrode 153 may correspond to the first upper electrode 143. For example, the second lower electrode 151 may be implemented integrally with the first lower electrode 141. Accordingly, the second lower electrode 151 of the second light-emitting element ED2 may be electrically connected to the first drain electrode 124 or the first source electrode 123 of the first transistor T1. In addition, the second light-emitting layer 152 may be implemented integrally with the first light-emitting layer 142, and the second upper electrode 153 may be implemented integrally with the first upper electrode 143. For example, the first light-emitting element ED1 and the second light-emitting element ED2 may be defined as one light-emitting element formed integrally with each other and receiving the same signal. Accordingly, the first light-emitting element ED1 may be defined as one portion of one light-emitting element, and the second light-emitting element ED2 may be defined as another portion of one light-emitting element. However, the present disclosure is not limited thereto, and in some cases, at least a portion of the configurations of the first light-emitting element ED1 and the second light-emitting element ED2 may be formed differently. For example, the first light-emitting element ED1 and the second light-emitting element ED2 may be formed as independent light-emitting elements connected to different transistors.

The third light-emitting element ED3 may implement the same color as the first light-emitting element ED1 disposed in the same sub-pixels RSP, GSP, and BSP. For example, the third light-emitting element ED3 may include the third lower electrode 161, a third light-emitting layer 162, and a third upper electrode 163 sequentially stacked on a substrate 110.

The third lower electrode 161 may correspond to the first lower electrode 141 and the second lower electrode 151, the third light-emitting layer 162 may correspond to the first light-emitting layer 142 and the second light-emitting layer 152, and the third upper electrode 163 may correspond to the first upper electrode 143 and the second upper electrode 153. For example, the third lower electrode 161 may have the same structure as the first lower electrode 141 and the second lower electrode 151, the third light-emitting layer 162 may have the same structure as the first light-emitting layer 142 and the second light-emitting layer 152, and the third upper electrode 163 may have the same structure as the first upper electrode 143 and the second upper electrode 153. The first lower electrode 141 and the second lower electrode 151 of each of the sub-pixels RSP, GSP, and BSP are connected to each other, and may be spaced apart from the third lower electrode 161 of the corresponding sub-pixels RSP, GSP, and BSP. Accordingly, the third lower electrode 161 of the third light-emitting element ED3 may be electrically connected to the second drain electrode 134 or the second source electrode 133 of the second transistor T2 through a contact hole penetrating the lower protective layer 114 and the overcoat layer 115. In addition, the third light-emitting layer 162 may be spaced apart from the first light-emitting layer 142 and the second light-emitting layer 152. Accordingly, in the display device according to the embodiment of the present disclosure, light emission due to leakage current may be suppressed. However, this is not limited to the above, and in some cases, at least some configurations of the first light-emitting element ED1, the second light-emitting element ED2, and the third light-emitting element ED3 may be formed differently.

According to an embodiment of the present disclosure, in the display device 100, light may be generated from the first light-emitting layer 142 and the second light-emitting layer 152 or only from the third light-emitting layer 162 depending on a user's selection or a pre-specified condition.

The bank 116 may be disposed in each of the sub-pixels RSP, GSP, and BSP. The bank 116 may include an insulating material. For example, the bank 116 may include an organic insulating material.

The first lower electrode 141 and the second lower electrode 151 of each of the sub-pixels RSP, GSP, and BSP may be insulated from the third lower electrode 161 of the corresponding sub-pixels RSP, GSP, and BSP by the bank 116. For example, the bank 116 may cover the edge of the first lower electrode 141 and the edge of the third lower electrode 161 between the first lower electrode 141 and the third lower electrode 161, and may cover the edge of the second lower electrode 151 and the edge of the third lower electrode 161 between the second lower electrode 151 and the third lower electrode 161.

The bank 116 may distinguish the first light-emitting areas RE1, GE1, and BE1 of the first light-emitting element ED1, the second light-emitting areas RE2, GE2, and BE2 of the second light-emitting element ED2, and the third light-emitting areas RE3, GE3, and BE3 of the third light-emitting element ED3. For example, the bank 116 may cover an edge area of the first lower electrode 141 to distinguish the first light-emitting areas RE1, GE1, and BE1 of the first light-emitting element ED1. The bank 116 may cover an edge area of the second lower electrode 151 to distinguish the second light-emitting areas RE2, GE2, and BE2 of the second light-emitting element ED2. The bank 116 may cover the edge area of the third lower electrode 161 to distinguish the third light-emitting areas RE3, GE3, and BE3 of the third light-emitting element ED3. In this case, the bank 116 may cover a portion of one lower electrode disposed in the first optical areas RNE, GNE, and BNE to distinguish the first light-emitting areas RE1, GE1, and BE1 of the first light-emitting element ED1 and the second light-emitting areas RE2, GE2, and BE2 of the second light-emitting element ED2. For example, the first lower electrode 141 of the first light-emitting element ED1 and the second lower electrode 151 of the second light-emitting element ED2 may be connected to each other to form one lower electrode, and the bank 116 may cover a portion of one lower electrode to distinguish the first lower electrode 141 and the second lower electrode 151. For example, the bank 116 may cover the boundary between the first lower electrode 141 and the second lower electrode 151. In this case, the portion of the first lower electrode 141 exposed by the bank 116 may be defined as the first light-emitting areas RE1, GE1, and BE1, and the portion of the second lower electrode 151 exposed by the bank 116 may be defined as the second light-emitting areas RE2, GE2, and BE2. Meanwhile, referring to FIG. 4, the sizes of the third light-emitting areas RE3, GE3, and BE3 of the third light-emitting element ED3 distinguished within each of the sub-pixels RSP, GSP, and BSP may be larger than the sizes of the first light-emitting areas RE1, GE1, and BE1 of the first light-emitting element ED1 and the size of the second light-emitting areas RE2, GE2, and BE2 of the second light-emitting element ED2, but is not limited thereto. In addition, the sizes of the first light-emitting areas RE1, GE1, and BE1 of the first light-emitting element ED1 distinguished within the sub-pixels RSP, GSP, and BSP and the sizes of the second light-emitting areas RE2, GE2, and BE2 of the second light-emitting element ED2 may be the same, but are not limited thereto.

The first light-emitting layer 142 and the first upper electrode 143 of the first light-emitting element ED1 located within each of the sub-pixels RSP, GSP, and BSP may be stacked on a portion of the corresponding first lower electrode 141 exposed by the bank 116. Specifically, the first light-emitting layer 142 and the first upper electrode 143 may be stacked on a portion of the corresponding first lower electrode 141 exposed by the bank 116 and the bank 116. The second light-emitting layer 152 and the second upper electrode 153 of the second light-emitting element ED2 located within each of the sub-pixels RSP, GSP, and BSP may be stacked on a portion of the corresponding second lower electrode 151 exposed by the bank 116. Specifically, the second light-emitting layer 152 and the second upper electrode 153 may be stacked on a portion of the corresponding second lower electrode 151 exposed by the bank 116 and on the bank 116. The third light-emitting layer 162 and the third upper electrode 163 of the third light-emitting element ED3 located within each of the sub-pixels RSP, GSP, and BSP may be stacked on a portion of the corresponding third lower electrode 161 exposed by the bank 116. Specifically, the third light-emitting layer 162 and the third upper electrode 163 may be stacked on a portion of the corresponding third lower electrode 161 exposed by the bank 116 and on the bank 116.

The first upper electrode 143 and the second upper electrode 153 of each of the sub-pixels RSP, GSP, and BSP may be electrically connected to the third upper electrode 163 of the corresponding sub-pixels RSP, GSP, and BSP. For example, the voltage applied to the first upper electrode 143 of the first light-emitting element ED1 located within each of the sub-pixels RSP, GSP, and BSP and the voltage applied to the second upper electrode 153 of the second light-emitting element ED2 may be the same as the voltage applied to the third upper electrode 163 of the third light-emitting element ED3 located within the corresponding sub-pixels RSP, GSP, and BSP. The first upper electrode 143 and the second upper electrode 153 of each of the sub-pixels RSP, GSP, and BSP may include the same material as the third upper electrode 163 of the corresponding sub-pixels RSP, GSP, and BSP. For example, the first upper electrode 143 and the second upper electrode 153 of each of the sub-pixels RSP, GSP, and BSP may be formed simultaneously with the third upper electrode 163 of the corresponding sub-pixels RSP, GSP, and BSP. The first upper electrode 143 and the second upper electrode 153 of each of the sub-pixels RSP, GSP, and BSP may extend onto the bank 116 and directly contact the third upper electrode 163 of the corresponding sub-pixels RSP, GSP, and BSP.

An encapsulating member 180 may be positioned on the first light-emitting element ED1, the second light-emitting element ED2, and the third light-emitting element ED3 of each of the sub-pixels RSP, GSP, and BSP. The encapsulating member 180 may suppress damage to the light-emitting elements ED1, ED2, and ED3 due to moisture and impact from the outside. The encapsulating member 180 may have a multilayer structure. For example, the encapsulating member 180 may include a first encapsulating layer 181, a second encapsulating layer 182, and a third encapsulating layer 183 that are sequentially stacked, but is not limited thereto.

The first encapsulating layer 181, the second encapsulating layer 182, and the third encapsulating layer 183 may include an insulating material. The second encapsulating layer 182 may include a different material from the first encapsulating layer 181 and the third encapsulating layer 183. For example, the first encapsulating layer 181 and the third encapsulating layer 183 may be inorganic encapsulating layers including inorganic insulating materials, and the second encapsulating layer 182 may include an organic encapsulating layer including an organic insulating material. Accordingly, in the light-emitting elements ED1 and ED2 of the display device 100, damage caused by moisture and impact from the outside may be effectively suppressed.

The black matrix BM may be disposed on the encapsulating member 180. The black matrix BM may be disposed to reduce the mixing of colors of the plurality of sub-pixels RSP, GSP, and BSP between the plurality of sub-pixels RSP, GSP, and BSP. Accordingly, the black matrix BM may be disposed to overlap the bank 116.

The first light-blocking pattern P1 may be disposed on the encapsulating member 180. The first light-blocking pattern P1 may be in the first optical areas RNE, GNE, and BNE located within each of the sub-pixels RSP, GSP, and BSP. For example, the first light-blocking pattern P1 may be disposed in the second light-emitting areas RE2, GE2, and BE2 of the first optical areas RNE, GNE, and BNE.

The first light-blocking pattern P1 is disposed on the same layer as the black matrix BM and may be made of the same material as the black matrix BM. Here, the first light-blocking pattern P1 may limit the path of light generated by the second light-emitting element ED2. For example, the first light-blocking pattern P1 may be disposed to reduce the brightness for some viewing angles in the second light-emitting areas RE2, GE2, and BE2.

The first light-blocking pattern P1 may be disposed to overlap the centers of the second light-emitting areas RE2, GE2, and BE2, that is, the center of the second light-emitting element ED2, thereby reducing the center brightness of the second light-emitting areas RE2, GE2, and BE2. In addition, the first light-blocking pattern P1 may be disposed to overlap the center of the second optical member 172. The center axis of the first light-blocking pattern P1, the center axis of the second optical member 172, and the center axis of the second light-emitting element ED2 may be coincident with each other. Accordingly, light emitted through the second optical member 172 may be provided in the first viewing angle range, but may be provided in a state where the center brightness is reduced. For example, when the distance between the second light-emitting element ED2 and the first light-blocking pattern P1 in the third direction Z is H1, and half of the length of the first light-blocking pattern P1 in the first direction X is d1, the first light-blocking pattern P1 may restrict the propagation of light having a viewing angle less than or equal to tan⁻¹(d1/H1) of the light emitted from the second light-emitting element ED2.

Meanwhile, the first light-blocking pattern P1 may not be disposed in the first light-emitting areas RE1, GE1, and BE1 of the first optical areas RNE, GNE, and BNE and the second optical areas RWE, GWE, and BWE.

The touch insulating layer 117 may be disposed on the black matrix BM.

The touch insulating layer 117 may be disposed between the encapsulating member 180 and the black matrix BM and the barrier layer 118 to insulate the barrier layer 118.

The touch insulating layer 117 may include an insulating material. For example, the touch insulating layer 117 may include, but is not limited to, an organic insulating material or an inorganic insulating material.

A plurality of barrier layers 118 may be positioned on the touch insulating layer 117. The plurality of barrier layers 118 may be disposed above the first light-emitting element ED1, the second light-emitting element ED2, and the third light-emitting element ED3 in the display area.

Referring to FIGS. 5 and 6, the plurality of barrier layers 118 may be disposed to overlap the bank 116 and the black matrix BM. Meanwhile, referring to FIG. 6, the plurality of barrier layers 118 may limit the path of light generated by the first light-emitting element ED1 and the second light-emitting element ED2. For example, the plurality of barrier layers 118 may be disposed to overlap edges of the first light-emitting areas RE1, GE1, and BE1 and the second light-emitting areas RE2, GE2, and BE2, thereby blocking light that propagates in the side direction of the light emitted from the first light-emitting areas RE1, GE1, and BE1 and the second light-emitting areas RE2, GE2, and BE2.

For example, when the distance between the second light-emitting element ED2 and the barrier layer 118 in the third direction Z is H2, and the distance between the center of the second light-emitting element ED2 and the end of the barrier layer 118 in the first direction X is d2, the barrier layer 118 may limit the viewing angle of the second light-emitting element ED2 to tan⁻¹(d2/H2). Meanwhile, when the distance between the center of the second light-emitting element ED2 and the end of the barrier layer 118 in the first direction X is the same as the distance between the center of the first light-emitting element ED1 and the end of the barrier layer 118 in the first direction X, the barrier layer 118 may limit the viewing angle of the first light-emitting element ED1 to tan⁻¹(d2/H2). That is, the plurality of barrier layers 118, together with the first optical member 171 and the second optical member 172, may block light that propagates in the side direction of the light emitted from the first optical areas RNE, GNE, and BNE located within each of the sub-pixels RSP, GSP, and BSP.

The plurality of barrier layers 118 may be made of the same material as the plurality of touch electrodes. For example, the plurality of barrier layers 118 may include a metal material such as titanium (Ti), aluminum (Al), silver (Ag), copper (Cu), magnesium-silver alloy (Mg:Ag), or the like, but is not limited thereto. Meanwhile, a touch buffer layer may be further disposed between the encapsulating member 180 and the barrier layer 118, but is not limited thereto.

Although not illustrated in the drawing, a plurality of touch electrodes may be disposed on the touch insulating layer 117. The plurality of touch electrodes may be disposed to be spaced apart from each other on the touch insulating layer 117. The plurality of touch electrodes may be configured to sense an external touch input using a user's finger or a touch pen, or the like. In addition, a touch bridge electrode may also be disposed on the encapsulating member 180 in addition to the touch electrodes, but is not limited thereto.

Referring to FIGS. 5 and 6, the first optical member 171, the second optical member 172, and the third optical member 173 may be disposed on the touch insulating layer 117.

The first optical member 171, the second optical member 172, and the third optical member 173 may be disposed on the same layer as the plurality of barrier layers 118 on the touch insulating layer 117. For example, the first optical member 171, the second optical member 172, and the third optical member 173 may be disposed to cover edges of the plurality of barrier layers 118, respectively.

The first optical member 171 may be disposed on the first light-emitting element ED1. Light generated by the first light-emitting element ED1 of each of the sub-pixels RSP, GSP, and BSP may be emitted through the first optical member 171 disposed in the first optical areas RNE, GNE, and BNE of the corresponding sub-pixels RSP, GSP, and BSP. The first optical member 171 may limit the propagation direction of the passing light to the first direction X and/or the second direction Y. For example, the planar shape of the first optical member 171 positioned within each of the sub-pixels RSP, GSP, and BSP may have a circular shape. For example, the first optical member 171 may have a hemispherical shape. However, the present disclosure is not limited thereto, and the planar shape of the first optical member 171 positioned within each of the sub-pixels RSP, GSP, and BSP may also have a polygonal shape.

The second optical member 172 may be disposed on the second light-emitting element ED2. Light generated by the second light-emitting element ED2 of each of the sub-pixels RSP, GSP, and BSP may be emitted through the second optical member 172 disposed in the first optical areas RNE, GNE, and BNE of the corresponding sub-pixels RSP, GSP, and BSP. The second optical member 172 may limit the propagation direction of the passing light to the first direction X and/or the second direction Y. For example, the shape of the second optical member 172 positioned within each of the sub-pixels RSP, GSP, and BSP may be the same as the shape of the first optical member 171. For example, the planar shape of the second optical member 172 may have a circular shape. For example, the second optical member 172 may have a hemispherical shape. However, it is not limited thereto, and the planar shape of the second optical member 172 located within each of the sub-pixels RSP, GSP, and BSP may have a polygonal shape.

In this case, the propagation direction of light emitted from the first optical areas RNE, GNE, and BNE of each of the sub-pixels RSP, GSP, and BSP may be limited to the first direction X and/or the second direction Y. For example, content (or image) provided by the first optical areas RNE, GNE, and BNE of each of the sub-pixels RSP, GSP, and BSP may not be shared with people around the user. Accordingly, content provided by light emitted through the first optical member 171 and the second optical member 172 may be provided in the first viewing angle range that is a narrower viewing angle than content provided by light emitted through the third optical member 173. For example, the content provided by light emitted through the first optical member 171 may be provided in a narrow field of view mode (private mode).

The third optical member 173 may be disposed on the third light-emitting element ED3. Light generated by the third light-emitting element ED3 of each of the sub-pixels RSP, GSP, and BSP may be emitted through the third optical member 173 disposed in the second optical areas RWE, GWE, and BWE of the corresponding sub-pixels RSP, GSP, and BSP.

The third optical member 173 may have a different shape from the first optical member 171 and the second optical member 172. The third optical member 173 may have a shape in which light in at least one direction may not be restricted. For example, the planar shape of the third optical member 173 positioned within each of the sub-pixels RSP, GSP, and BSP may have a bar shape extending in the first direction X. For example, the third optical member 173 may have a semi-cylindrical shape extending in the first direction X.

In this case, the propagation direction of the light emitted from the second optical areas RWE, GWE, and BWE of each of the sub-pixels RSP, GSP, and BSP may not be limited to the first direction X. For example, the content (or image) provided through the second optical areas RWE, GWE, and BWE of each of the sub-pixels RSP, GSP, and BSP may be shared with the user and surrounding people adjacent in the first direction X. Accordingly, the content provided by light emitted through the third optical member 173 may be provided in the second viewing angle range that is a wider viewing angle than content provided by light emitted through the first optical member 171 and the second optical member 172. For example, the content provided by light emitted through the third optical member 173 may be provided in a wide field of view mode (share mode).

The first light-emitting areas RE1, GE1, and BE1 of each of the sub-pixels RSP, GSP, and BSP may have a shape corresponding to the first optical member 171 of the corresponding sub-pixels RSP, GSP, and BSP. For example, the planar shape of the first light-emitting areas RE1, GE1, and BE1 of each of the sub-pixels RSP, GSP, and BSP may have a circular or polygonal shape. The first optical member 171 may have a larger size than the first light-emitting areas RE1, GE1, and BE1 of the corresponding sub-pixels RSP, GSP, and BSP. Accordingly, the efficiency of light emitted from the first light-emitting areas RE1, GE1, and BE1 of the sub-pixels RSP, GSP, and BSP may be improved.

The second light-emitting areas RE2, GE2, and BE2 of each of the sub-pixels RSP, GSP, and BSP may have a shape corresponding to the second optical member 172 of the corresponding sub-pixels RSP, GSP, and BSP. For example, the planar shape of the second light-emitting areas RE2, GE2, and BE2 of each of the sub-pixels RSP, GSP, and BSP may have a circular or polygonal shape. The second optical member 172 may have a larger size than the second light-emitting areas RE2, GE2, and BE2 of the corresponding sub-pixels RSP, GSP, and BSP. Accordingly, the efficiency of light emitted from the second light-emitting areas RE2, GE2, and BE2 of the sub-pixels RSP, GSP, and BSP may be improved.

The third light-emitting areas RE3, GE3, and BE3 of each pixel PX may have a shape corresponding to the third optical member 173 of the corresponding sub-pixels RSP, GSP, and BSP. For example, the planar shape of the third light-emitting areas RE3, GE3, and BE3 of each of the sub-pixels RSP, GSP, and BSP may have a bar shape extending in the first direction X. The third optical member 173 may have a larger size than the third light-emitting areas RE3, GE3, and BE3 of the corresponding sub-pixels RSP, GSP, and BSP. Accordingly, the efficiency of light emitted from the third light-emitting areas RE3, GE3, and BE3 of the sub-pixels RSP, GSP, and BSP may be improved.

The optical member protective layer 119 may be positioned on the first optical member 171, the second optical member 172, and the third optical member 173 of the sub-pixels RSP, GSP, and BSP. The optical member protective layer 119 may include an insulating material. For example, the optical member protective layer 119 may include an organic insulating material. The refractive index of the optical member protective layer 119 may be lower than the refractive index of the first optical member 171, the refractive index of the second optical member 172, and the refractive index of the third optical member 173 positioned within each of the sub-pixels RSP, GSP, and BSP. Accordingly, in the display device 100 according to the embodiment of the present disclosure, light passing through the first optical member 171, the second optical member 172, and the third optical member 173 of each of the sub-pixels RSP, GSP, and BSP may not be reflected toward the substrate 110 due to the difference in refractive index with respect to the optical member protective layer 119.

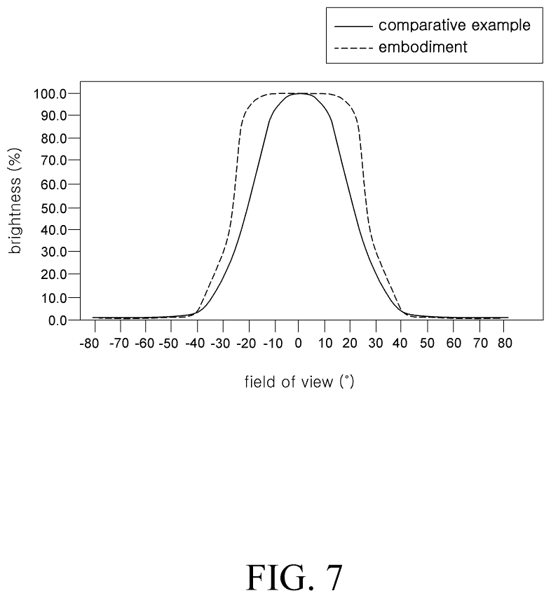

Below, with reference to FIG. 7, the brightness according to the viewing angle in the first optical areas RNE, GNE, and BNE is described.

FIG. 7 is a graph for explaining brightness according to the viewing angle of the display device according to one embodiment of the present disclosure. The embodiment of FIG. 7 illustrates brightness according to the viewing angle in the first optical areas RNE, GNE, and BNE of the display device 100 according to one embodiment of the present disclosure. The comparative example is different from the embodiment of the present disclosure only in that the first light-blocking pattern P1 is not disposed.

In FIG. 7, the front direction is defined as having a viewing angle of 0°, and the brightness in the front direction is defined as 100% in each of the comparative examples and the embodiment.

Referring to FIG. 7, it may be confirmed that both the comparative example and the embodiment limit the viewing angle to about −40° or less and about 40° or more, and provide light in a range of a viewing angle of about −40° to about 40°.

The comparative example exhibits the brightness of about 90% at the viewing angle of about −10° to about 10°, and it may be confirmed that the brightness decreases to less than about 90% at viewing angles of about −10° or less and about 10° or more. Meanwhile, the embodiment exhibits the brightness of about 90% at a viewing angle of about −20° to about 20°, and it may be confirmed that the brightness decreases to less than about 90% at viewing angles of about −20° or less and about 20° or more. In addition, it may be confirmed that the brightness of the embodiment increases more than the brightness of the comparative example at the viewing angle of about −30° to about −10° and the viewing angle of about 10° to about 30°.

When the display device is applied to a vehicle, the field of view of at least a portion of the display device needs to be limited according to the user's needs. For example, it is necessary to limit the propagation direction of light passing through the optical member by disposing the optical member on the light-emitting element. However, when light emitted through the optical member provides the image in the narrow field of view mode, the higher the angle, the more the light transmitted through the optical member is refracted, and the emitted light is limited. For example, in the case of the image in a narrow field of view mode, the light emitted from the display device is limited as the viewing angle increases. Accordingly, the viewing angle deviation between the front surface and the side surface may be severe. For example, when light emitted through the optical member is provided in a range of a viewing angle of about −40° to about 40°, the brightness may exhibit about 20% to about 70% compared to the front surface at the viewing angle of about −30° to about −20° and the viewing angle of about 20° to about 30°.

Accordingly, the display device 100 according to one embodiment of the present disclosure may improve the brightness deviation according to the viewing angle by disposing the plurality of first light-blocking patterns P1 in the first optical areas RNE, GNE, and BNE in which the propagation direction of the light is limited to the first direction X and/or the second direction Y. For example, the first light-blocking pattern P1 disposed in the first optical areas RNE, GNE, and BNE may be disposed in the center of the second light-emitting areas RE2, GE2, and BE2 to reduce the center brightness of the second light-emitting areas RE2, GE2, and BE2. Accordingly, the relative ratio of the side brightness of the second light-emitting areas RE2, GE2, and BE2 propagating between the first light-blocking pattern P1 and the barrier layer 118 to the center brightness of the second light-emitting areas RE2, GE2, and BE2 may increase. Accordingly, the light emitted from the second light-emitting areas RE2, GE2, and BE2 among the first optical areas RNE, GNE, and BNE may compensate for the brightness with respect to the brightness at the side viewing angle in the disposed first light-emitting areas RE1, GE1, and BE1, for example, the brightness at the viewing angle of about −30° to about −20° and at the viewing angle of about 20° to about 30°. Accordingly, the deviation according to the viewing angle of the image displayed from the first optical areas RNE, GNE, and BNE of each of the sub-pixels RSP, GSP, and BSP may be reduced, and user visibility may be improved. Accordingly, the area limiting the image required in the narrow viewing angle mode may be clarified.

In addition, the display device 100 according to one embodiment of the present disclosure reduces the deviation according to the viewing angle of the image by reducing the center brightness of the second light-emitting element ED2 without increasing the overall brightness of the first light-emitting element ED1 and/or the second light-emitting element ED2 disposed in the first optical areas RNE, GNE, and BNE in order to improve the side brightness in the first optical areas RNE, GNE, and BNE. Accordingly, deterioration of the first light-emitting element ED1 and/or the second light-emitting element ED2 disposed in the first optical areas RNE, GNE, and BNE is suppressed, low-power driving is possible, and the lifespan of the display device 100 may be improved.

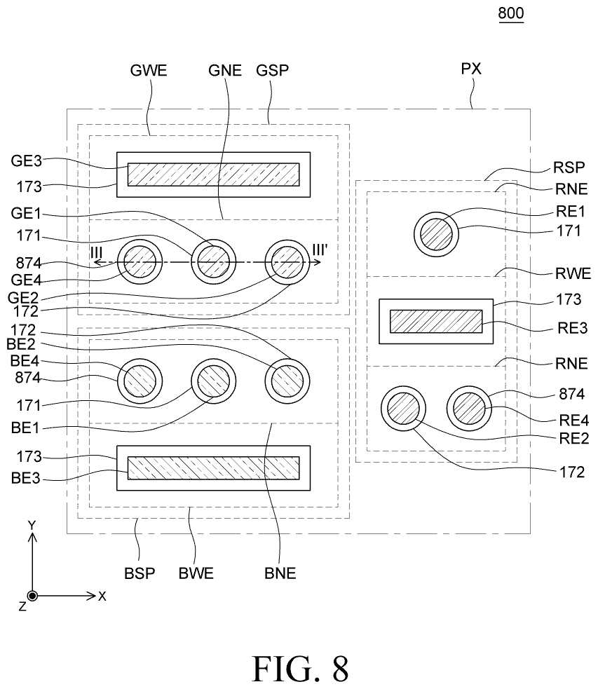

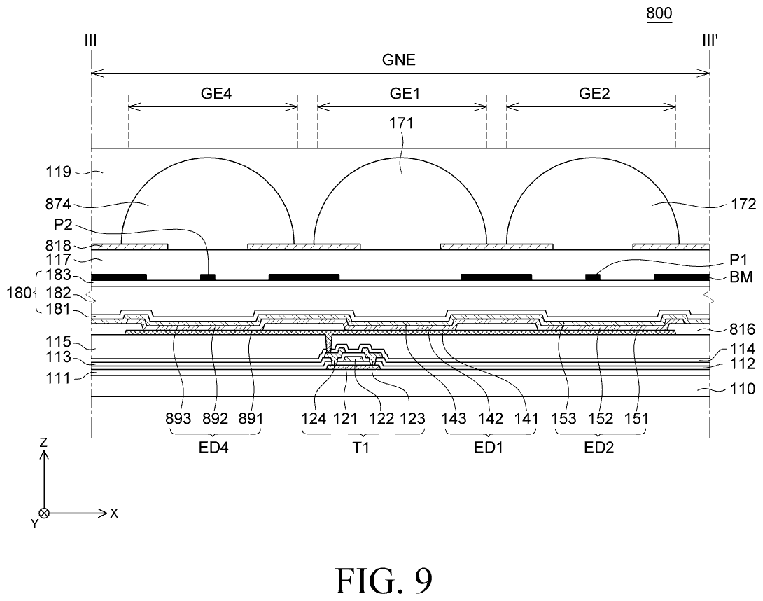

FIG. 8 is an enlarged plan view illustrating the disposition of optical members included in a display device according to another embodiment of the present disclosure. FIG. 9 is a cross-sectional view according to III-III′ of FIG. 8. FIG. 9 illustrates a pixel PX in which the first optical member 171, the second optical member 172, and a fourth optical member 874 are disposed. The display device 800 of FIGS. 8 and 9 is different from the display device 100 of FIGS. 1 to 6 only in that a bank 816 and a plurality of barrier layers 818 are different, and a fourth light-emitting element ED4 and a second light-blocking pattern P2 are added, and the other configurations are substantially the same, so a duplicate description is omitted.

For convenience of explanation, in FIG. 9, only the area corresponding to the first optical area GNE of the second sub-pixel GSP among the three sub-pixels RSP, GSP, and BSP illustrated in FIG. 8 is illustrated, but other sub-pixels RSP and BSP may also be formed with the same configuration.

The fourth light-emitting element ED4 may be disposed in the first optical areas RNE, GNE, and BNE of each of the sub-pixels RSP, GSP, and BSP. For example, one pixel PX may include the fourth light-emitting element ED4 disposed in the first optical area RNE of the first sub-pixel RSP, the fourth light-emitting element ED4 disposed in the first optical area GNE of the second sub-pixel GSP, and the fourth light-emitting element ED4 disposed in the first optical area BNE of the third sub-pixel BSP.

Meanwhile, in FIG. 9, the fourth light-emitting element ED4, the first light-emitting element ED1, and the second light-emitting element ED2 are sequentially disposed in the first direction X in the second sub-pixel GSP and the third sub-pixel BSP. Moreover, the second light-emitting element ED2 and the fourth light-emitting element ED4 are sequentially disposed in the first direction X in the first sub-pixel RSP, and the fourth light-emitting element ED4 is disposed spaced apart from the first light-emitting element ED1 in the second direction X. However, the disposition of the fourth light-emitting element ED4 in each of the sub-pixels RSP, GSP, and BSP may not be limited thereto. For example, the fourth light-emitting element ED4 may be disposed in consideration of the light-emitting efficiency and area of each of the sub-pixels RSP, GSP, and BSP.

In this case, the fourth light-emitting element ED4 may implement the same color as the first light-emitting element ED1, the second light-emitting element ED2, and the third light-emitting element ED3 disposed in the same sub-pixels RSP, GSP, and BSP.

The fourth light-emitting element ED4 may include a fourth lower electrode 891, a fourth light-emitting layer 892, and a fourth upper electrode 893 sequentially stacked on the substrate 110.

The fourth lower electrode 891 may correspond to the first lower electrode 141 and the second lower electrode 151. For example, the fourth lower electrode 891 may be implemented integrally with the first lower electrode 141 and the second lower electrode 151. Referring to FIG. 9, the fourth lower electrode 891 of the fourth light-emitting element ED4 may be electrically connected to the drain electrode 124 of the first transistor T1. Accordingly, the fourth light-emitting element ED4 may emit light together with the first light-emitting element ED1 and the second light-emitting element ED2 connected to the first transistor T1. In addition, the fourth light-emitting element ED4 may emit light individually with the third light-emitting element ED3 connected to the second transistor T2.

The bank 816 may be disposed in each of the sub-pixels RSP, GSP, and BSP.

The bank 816 may distinguish the first light-emitting areas RE1, GE1, and BE1 of the first light-emitting element ED1, the second light-emitting areas RE2, GE2, and BE2 of the second light-emitting element ED2, the third light-emitting areas RE3, GE3, and BE3 of the third light-emitting element ED3, and fourth light-emitting areas RE4, GE4, and BE4 of the fourth light-emitting element ED4.

Meanwhile, as illustrated in FIG. 9, the first lower electrode 141 of the first light-emitting element ED1, the second lower electrode 151 of the second light-emitting element ED2, and the fourth lower electrode 891 of the fourth light-emitting element ED4 may be connected to each other to form one lower electrode. In this case, the bank 816 may cover a portion of one lower electrode to distinguish between the first lower electrode 141, the second lower electrode 151, and the fourth lower electrode 891. For example, the bank 816 may be disposed at the boundary between the first lower electrode 141 and the second lower electrode 151 and the boundary between the second lower electrode 151 and the fourth lower electrode 891, to distinguish between the first lower electrode 141, the second lower electrode 151, and the fourth lower electrode 891.

A portion of the first lower electrode 141 exposed by the bank 816 may be defined as the first light-emitting areas RE1, GE1, and BE1, a portion of the second lower electrode 151 exposed by the bank 816 may be defined as the second light-emitting areas RE2, GE2, and BE2, and a portion of the fourth lower electrode 891 exposed by the bank 816 may be defined as the fourth light-emitting areas RE4, GE4, and BE4.

Meanwhile, although not illustrated in the drawings, the fourth lower electrode 891 of each of the sub-pixels RSP, GSP, and BSP may be insulated from the third lower electrode 161 of the corresponding sub-pixels RSP, GSP, and BSP by the bank 816. For example, the bank 816 may cover the edge of the fourth lower electrode 891 and the edge of the third lower electrode 161 between the fourth lower electrode 891 and the third lower electrode 161.

Meanwhile, referring to FIG. 8, the sizes of the fourth light-emitting areas RE4, GE4, and BE4 of the fourth light-emitting element ED4 separated within each of the sub-pixels RSP, GSP, and BSP may be smaller than the sizes of the third light-emitting areas RE3, GE3, and BE3 of the third light-emitting element ED3, but is not limited thereto. In addition, the fourth light-emitting areas RE4, GE4, and BE4 of the fourth light-emitting element ED4 separated within the sub-pixels RSP, GSP, and BSP may be the same as the sizes of the first light-emitting areas RE1, GE1, and BE1 of the first light-emitting element ED1 and the sizes of the second light-emitting areas RE2, GE2, and BE2 of the second light-emitting element ED2, but is not limited thereto.

The fourth light-emitting layer 892 and the fourth upper electrode 893 of the fourth light-emitting element ED4 located within each of the sub-pixels RSP, GSP, and BSP may be stacked on a portion of the fourth lower electrode 891 exposed by the bank 816.

The fourth light-emitting layer 892 may correspond to the first light-emitting layer 142 and the second light-emitting layer 152. For example, the fourth light-emitting layer 892 may be implemented integrally with the first light-emitting layer 142 and the second light-emitting layer 152.

The fourth upper electrode 893 may correspond to the first upper electrode 143 and the second upper electrode 153. For example, the fourth upper electrode 893 may be implemented integrally with the first upper electrode 143 and the second upper electrode 153. In addition, the fourth upper electrode 893 of each of the sub-pixels RSP, GSP, and BSP may be electrically connected to the first upper electrode 143, the second upper electrode 153, and the third upper electrode 163 so that the same voltage may be applied thereto.

Accordingly, the fourth light-emitting element ED4 may be defined as a single light-emitting element that is formed integrally with the first light-emitting element ED1 and the second light-emitting element ED2 and receives the same signal. For example, the first light-emitting element ED1 may be defined as a portion of one light-emitting element, the second light-emitting element ED2 may be defined as another portion of one light-emitting element, and the fourth light-emitting element ED4 may be defined as still another portion of one light-emitting element. However, this is not limited thereto, and in some cases, the fourth light-emitting element ED4 may be formed as an independent light-emitting element that is connected to different transistors from the first light-emitting element ED1 and the second light-emitting element ED2.

The second light-blocking pattern P2 may be disposed on the encapsulating member 180. The second light-blocking pattern P2 may be disposed in the first optical areas RNE, GNE, and BNE located within each of the sub-pixels RSP, GSP, and BSP. For example, the second light-blocking pattern P2 may be disposed in the fourth light-emitting areas RE4, GE4, and BE4 of the first optical areas RNE, GNE, and BNE.

The second light-blocking pattern P2 may be disposed on the same layer as the black matrix BM and may be made of the same material as the black matrix BM. Accordingly, the second light-blocking pattern P2 may limit the path of light generated by the fourth light-emitting element ED4. For example, the second light-blocking pattern P2 may be disposed to reduce brightness for some viewing angles in the fourth light-emitting areas RE4, GE4, and BE4.

The second light-blocking pattern P2 may be disposed to overlap the center of the fourth light-emitting areas RE4, GE4, and BE4, that is, the center of the fourth light-emitting element ED4, thereby reducing the center brightness of the fourth light-emitting areas RE4, GE4, and BE4. In addition, the second light-blocking pattern P2 may be disposed to overlap the center of the fourth optical member 874. The center axis of the second light-blocking pattern P2, the center axis of the fourth optical member 874, and the center axis of the fourth light-emitting element ED4 may be coincident with each other. Accordingly, light emitted through the fourth optical member 874 may be provided in the first viewing angle range, but may be provided in a state where the center brightness is reduced.

Meanwhile, the second light-blocking pattern P2 may not be disposed in the first light-emitting areas RE1, GE1, and BE1 of the first optical areas RNE, GNE, and BNE and the second optical areas RWE, GWE, and BWE.

The plurality of barrier layers 818 may be positioned on the touch insulating layer 117. The plurality of barrier layers 818 may be disposed above the first light-emitting element ED1, the second light-emitting element ED2, the third light-emitting element ED3, and the fourth light-emitting element ED4 in the display area.

The plurality of barrier layers 818 are disposed to overlap the edges of the first light-emitting areas RE1, GE1, and BE1, the second light-emitting areas RE2, GE2, and BE2, and the fourth light-emitting areas RE4, GE4, and BE4, so as to block light that propagates in the side direction among the light emitted from the first light-emitting areas RE1, GE1, and BE1, the second light-emitting areas RE2, GE2, and BE2, and the fourth light-emitting areas RE4, GE4, and BE4. That is, the plurality of barrier layers 818, together with the first optical member 171, the second optical member 172, and the fourth optical member 874, may block light that propagates in the side direction of the light emitted from the first optical areas RNE, GNE, and BNE.

Referring to FIGS. 8 and 9, the fourth optical member 874 may be disposed on the touch insulating layer 117. The fourth optical member 874 may be disposed so as to overlap the fourth light-emitting areas RE4, GE4, and BE4 of the fourth light-emitting element ED4 in the first optical areas RNE, GNE, and BNE of each of the sub-pixels RSP, GSP, and BSP.

The fourth optical member 874 may be disposed on the same layer as the plurality of barrier layers 818 on the touch insulating layer 117. For example, the fourth optical member 874 may be disposed to cover the edges of the plurality of barrier layers 818.

The fourth optical member 874 may be disposed on the fourth light-emitting element ED4. Light generated by the fourth light-emitting element ED4 of each of the sub-pixels RSP, GSP, and BSP may be emitted through the fourth optical member 874 disposed in the first optical areas RNE, GNE, and BNE of the corresponding sub-pixels RSP, GSP, and BSP. The fourth optical member 874 may limit the propagation direction of the passing light to the first direction X and/or the second direction Y. For example, the shape of the fourth optical member 874 positioned within each of the sub-pixels RSP, GSP, and BSP may be the same as the shape of the first optical member 171 and the shape of the second optical member 172. For example, the planar shape of the fourth optical member 874 may have a circular shape. For example, the fourth optical member 874 may have a hemispherical shape. However, it is not limited thereto, and the planar shape of the fourth optical member 874 located within each of the sub-pixels RSP, GSP, and BSP may have a polygonal shape.

Accordingly, content provided by light emitted through the fourth optical member 874 may be provided in a first viewing angle range that is narrower than content provided by light emitted through the third optical member 173. For example, content provided by light emitted through the fourth optical member 874 may be provided in the narrow field of view mode (private mode).

The display device 800 according to another embodiment of the present disclosure may reduce the central brightness of the second light-emitting areas RE2, GE2, and BE2 and compensate for the brightness with respect to the side viewing angle of the first light-emitting areas RE1, GE1, and BE1 by disposing the first light-blocking pattern P1 at the center of the second light-emitting areas RE2, GE2, and BE2 among the first optical areas RNE, GNE, and BNE. Accordingly, the deviation according to the viewing angle of the image displayed from the first optical areas RNE, GNE, and BNE among each of the sub-pixels RSP, GSP, and BSP may be reduced, and user visibility may be improved. Accordingly, the area limiting the image required in the narrow viewing angle mode may be clarified.

The display device 800 according to another embodiment of the present disclosure may improve the overall brightness of the first optical areas RNE, GNE, and BNE by disposing the fourth light-emitting element ED4 in the first optical areas RNE, GNE, and BNE. The light-emitting element disposed in the first optical areas RNE, GNE, and BNE has a smaller size than the light-emitting element disposed in the second optical areas RWE, GWE, and BWE in order to limit the propagation direction of light to the first direction X and/or the second direction Y. Accordingly, when the number of light-emitting elements disposed in the first optical areas RNE, GNE, and BNE is the same as the number of light-emitting elements disposed in the second optical areas RWE, GWE, and BWE, the overall brightness of the first optical areas RNE, GNE, and BNE may be lower than the overall brightness of the second optical areas RWE, GWE, and BWE. Accordingly, the display device 800 according to another embodiment of the present disclosure may reduce a brightness difference between the first optical areas RNE, GNE, and BNE and the second optical areas RWE, GWE, and BWE by disposing the fourth light-emitting element ED4 in the first optical areas RNE, GNE, and BNE.

The display device 800 according to another embodiment of the present disclosure may reduce the central brightness of the fourth light-emitting areas RE4, GE4, and BE4 and compensate for the brightness with respect to the side viewing angle of the first light-emitting areas RE1, GE1, and BE1 by disposing the second light-blocking pattern P2 overlapping the fourth light-emitting areas RE4, GE4, and BE4 in the first optical areas RNE, GNE, and BNE. Accordingly, the deviation of the image displayed from the first optical areas RNE, GNE, and BNE among the sub-pixels RSP, GSP, and BSP according to the viewing angle may be reduced, and user visibility may be improved. Accordingly, the area limiting the image required in a narrow viewing angle mode may be clarified.

The exemplary embodiments of the present disclosure can also be described as follows:

According to an aspect of the present disclosure, there is provided a display device. The display device comprises a substrate having a plurality of sub-pixels defined, a plurality of first light-emitting elements disposed in each of the plurality of sub-pixels, a plurality of second light-emitting elements disposed in each of the plurality of sub-pixels, a plurality of first light-blocking patterns overlapping centers of the plurality of second light-emitting elements on the plurality of second light-emitting elements, a plurality of first optical members disposed above the plurality of first light-emitting elements and refracting light from the plurality of first light-emitting elements and a plurality of second optical members disposed above the plurality of second light-emitting elements and refracting light from the plurality of second light-emitting elements.

The display device may further comprise a bank disposed on the substrate and defining a light-emitting area of the plurality of first light-emitting elements and a light-emitting area of the plurality of second light-emitting elements and a black matrix overlapping the bank on the bank and disposed on the same layer as the plurality of first light-blocking patterns.

The plurality of first optical members and the plurality of second optical members may be disposed on the plurality of first light-blocking patterns.

Central axes of the plurality of first light-blocking patterns, central axes of the plurality of second optical members, and central axes of the plurality of second light-emitting elements may be coincident with each other.

The plurality of second light-emitting elements emit light of the same color as the plurality of first light-emitting elements, and the plurality of first optical members and the plurality of second optical members may have a hemispherical shape.

The display device may further comprise a plurality of third light-emitting elements disposed in each of the plurality of sub-pixels and emitting light of the same color as the plurality of first light-emitting elements and the plurality of second light-emitting elements and a plurality of third optical members disposed above the plurality of third light-emitting elements and refracting light from the plurality of third light-emitting elements, having a different shape from the plurality of first optical members and the plurality of second optical members.

The plurality of third optical members may have a semi-cylindrical shape.

The display device may further comprise a plurality of fourth light-emitting elements disposed in each of the plurality of sub-pixels and emitting light of the same color as the plurality of first light-emitting elements, the plurality of second light-emitting elements, and the plurality of third light-emitting elements, a plurality of fourth optical members disposed above the plurality of fourth light-emitting elements and refracting light from the plurality of fourth light-emitting elements and having the same shape as the plurality of first optical members and the plurality of second optical members; and a plurality of second light-blocking patterns overlapping the centers of the plurality of fourth light-emitting elements on the plurality of fourth light-emitting elements.

According to another aspect of the present disclosure, there is provided a display device. The display device comprises a substrate having a plurality of sub-pixels defined, a plurality of light-emitting elements disposed in each of the plurality of sub-pixels, a bank defining a light-emitting area of the plurality of light-emitting elements on the substrate, a plurality of optical members overlapping the light-emitting area of the plurality of light-emitting elements on the plurality of light-emitting elements and a plurality of first light-blocking patterns disposed in each of the plurality of sub-pixels on the plurality of light-emitting elements, wherein the plurality of light-emitting elements are disposed in each of the plurality of sub-pixels and include a plurality of first light-emitting elements and a plurality of second light-emitting elements that emit the same color, and the plurality of first light-blocking patterns overlap the center of the light-emitting area of the plurality of second light-emitting elements of the light-emitting area of the plurality of first light-emitting elements and the light-emitting area of the plurality of second light-emitting elements.

The plurality of optical members may include a plurality of first optical members overlapping the plurality of first light-emitting elements and a plurality of second optical members overlapping the plurality of second light-emitting elements and having the same shape as the plurality of first optical members.

The plurality of light-emitting elements may further include a plurality of third light-emitting elements that are disposed in each of the plurality of sub-pixels and emit light of the same color as the plurality of first light-emitting elements and the plurality of second light-emitting elements, and the plurality of optical members may further include a plurality of third optical members that are disposed on the plurality of third light-emitting elements and refract light from the plurality of third light-emitting elements and have a different shape from the plurality of first optical members and the plurality of second optical members.

The plurality of first optical members and the plurality of second optical members may have a hemispherical shape, and the plurality of third optical members have a semi-cylindrical shape.

The display device may further comprise a plurality of second light-blocking patterns disposed in each of the plurality of sub-pixels on the plurality of light-emitting elements, wherein the plurality of light-emitting elements may further include a plurality of fourth light-emitting elements disposed in each of the plurality of sub-pixels and emitting light of the same color as the plurality of first light-emitting elements, the plurality of second light-emitting elements, and the plurality of third light-emitting elements, the plurality of optical members may further include a plurality of fourth optical members disposed above the plurality of fourth light-emitting elements and refracting light from the plurality of fourth light-emitting elements, and having the same shape as the plurality of first optical members and the plurality of second optical members, and the plurality of second light-blocking patterns may overlap the centers of the plurality of fourth optical members.

Central axes of the plurality of second blocking patterns, central axes of the plurality of second optical members, and central axes of the plurality of second light-emitting elements may be coincident with each other.

The display device may further comprise a black matrix disposed on the same layer as the plurality of first light-blocking patterns and overlapping the bank.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display device, comprising:
a substrate having a plurality of sub-pixels defined;
a plurality of first light-emitting elements disposed in each of the plurality of sub-pixels;
a plurality of second light-emitting elements disposed in each of the plurality of sub-pixels;
a plurality of first light-blocking patterns overlapping centers of the plurality of second light-emitting elements on the plurality of second light-emitting elements;
a plurality of first optical members disposed above the plurality of first light-emitting elements and refracting light from the plurality of first light-emitting elements; and
a plurality of second optical members disposed above the plurality of second light-emitting elements and refracting light from the plurality of second light-emitting elements.

2. The display device according to claim 1, further comprising:
a bank disposed on the substrate and defining a light-emitting area of the plurality of first light-emitting elements and a light-emitting area of the plurality of second light-emitting elements; and
a black matrix overlapping the bank on the bank and disposed on the same layer as the plurality of first light-blocking patterns.

3. The display device according to claim 1, wherein the plurality of first optical members and the plurality of second optical members are disposed above the plurality of first light-blocking patterns.

4. The display device according to claim 1, wherein central axes of the plurality of first light-blocking patterns, central axes of the plurality of second optical members, and central axes of the plurality of second light-emitting elements are coincident with each other.

5. The display device according to claim 1, wherein the plurality of second light-emitting elements emit light of the same color as the plurality of first light-emitting elements, and
the plurality of first optical members and the plurality of second optical members have a hemispherical shape.

6. The display device according to claim 5, wherein further comprising:
a plurality of third light-emitting elements disposed in each of the plurality of sub-pixels and emitting light of the same color as the plurality of first light-emitting elements and the plurality of second light-emitting elements; and
a plurality of third optical members disposed above the plurality of third light-emitting elements and refracting light from the plurality of third light-emitting elements, having a different shape from the plurality of first optical members and the plurality of second optical members.

7. The display device according to claim 6, wherein the plurality of third optical members have a semi-cylindrical shape.

8. The display device according to claim 6, further comprising:
a plurality of fourth light-emitting elements disposed in each of the plurality of sub-pixels and emitting light of the same color as the plurality of first light-emitting elements, the plurality of second light-emitting elements, and the plurality of third light-emitting elements;
a plurality of fourth optical members disposed above the plurality of fourth light-emitting elements and refracting light from the plurality of fourth light-emitting elements and having the same shape as the plurality of first optical members and the plurality of second optical members; and
a plurality of second light-blocking patterns overlapping the centers of the plurality of fourth light-emitting elements on the plurality of fourth light-emitting elements.

9. A display device, comprising:
a substrate having a plurality of sub-pixels defined;
a plurality of light-emitting elements disposed in each of the plurality of sub-pixels;
a bank defining a light-emitting area of the plurality of light-emitting elements on the substrate;
a plurality of optical members overlapping the light-emitting area of the plurality of light-emitting elements on the plurality of light-emitting elements; and
a plurality of first light-blocking patterns disposed in each of the plurality of sub-pixels on the plurality of light-emitting elements,
wherein the plurality of light-emitting elements are disposed in each of the plurality of sub-pixels and include a plurality of first light-emitting elements and a plurality of second light-emitting elements that emit the same color, and
the plurality of first light-blocking patterns overlap the center of the light-emitting area of the plurality of second light-emitting elements among the light-emitting area of the plurality of first light-emitting elements and the light-emitting area of the plurality of second light-emitting elements.

10. The display device according to claim 9, wherein the plurality of optical members include a plurality of first optical members overlapping the plurality of first light-emitting elements and a plurality of second optical members overlapping the plurality of second light-emitting elements and having the same shape as the plurality of first optical members.

11. The display device according to claim 10, wherein the plurality of light-emitting elements further include a plurality of third light-emitting elements that are disposed in each of the plurality of sub-pixels and emit light of the same color as the plurality of first light-emitting elements and the plurality of second light-emitting elements, and
the plurality of optical members further include a plurality of third optical members that are disposed above the plurality of third light-emitting elements and refract light from the plurality of third light-emitting elements and have a different shape from the plurality of first optical members and the plurality of second optical members.

12. The display device according to claim 11, wherein the plurality of first optical members and the plurality of second optical members have a hemispherical shape, and the plurality of third optical members have a semi-cylindrical shape.

13. The display device according to claim 11, further comprising a plurality of second light-blocking patterns disposed in each of the plurality of sub-pixels on the plurality of light-emitting elements,
wherein the plurality of light-emitting elements further include a plurality of fourth light-emitting elements disposed in each of the plurality of sub-pixels and emitting light of the same color as the plurality of first light-emitting elements, the plurality of second light-emitting elements, and the plurality of third light-emitting elements,
the plurality of optical members further include a plurality of fourth optical members disposed above the plurality of fourth light-emitting elements and refracting light from the plurality of fourth light-emitting elements, and having the same shape as the plurality of first optical members and the plurality of second optical members, and
the plurality of second light-blocking patterns overlap the centers of the plurality of fourth optical members.

14. The display device according to claim 10, wherein central axes of the plurality of second blocking patterns, central axes of the plurality of second optical members, and central axes of the plurality of second light-emitting elements are coincident with each other.

15. The display device according to claim 9, further comprising a black matrix disposed on the same layer as the plurality of first light-blocking patterns and overlapping the bank.
